(19) United States
(12) Patent Application Publication
(10) Pub. No.: US 2019/0189363 A1
(43) Pub. Date: Jun. 20, 2019

(54) METHOD FOR FABRICATING A LAYER OF MATERIAL IN AN ORGANIC ELECTRONIC STRUCTURE, AN ORGANIC ELECTRONIC STRUCTURE AND A PEROVSKITE PRECURSOR INK FOR USE IN FABRICATING THE SAME

(71) Applicant: City University of Hong Kong, Kowloon (HK)

(72) Inventors: Sai Wing Tsang, Shatin (HK); Yuanhang Cheng, Tai Wai (HK); Xiuwen Xu, Kowloon (HK); Yuemin Xie, Hebei Province (CN)

(21) Appl. No.: 15/846,576

(22) Filed: Dec. 19, 2017

(51) Int. Cl. H01G 9/20; H01L 51/00; C09D 11/52

(52) U.S. Cl. CPC H01G 9/2059; H01L 51/0007; H01L 51/0028; H01L 51/0097; H01L 51/0077; C09D 11/52; H01L 51/4246; H01L 51/0035; H01L 51/0039; H01L 51/0046; H01L 51/0047; H01L 51/0072; H01L 51/0037

(57) ABSTRACT

A method for fabricating a layer of material in an organic electronic structure, an organic electronic structure and a perovskite precursor ink for use in fabricating the same. The method includes the steps of: reducing moisture and oxygen content on a surface of a substrate; depositing the material contained in a solution on the surface of the substrate; and facilitating crystallization of the material contained in the solution applied on the surface so as to form the layer of material.

### TECHNICAL FIELD

The present invention relates to a method for fabricating a layer of material in an organic electronic structure, an organic electronic structure and a perovskite precursor ink for use in fabricating the same, specifically, although not exclusively, to a method for fabricating an perovskite solar cell structure in an air-ambient.

### BACKGROUND

Electronic devices are components in various electrical appliances and equipment. Examples of these devices include light emitting diodes (LEDs), solar cells, photonic devices, transistors or computer processors which may be included to provide different functions in an electrical apparatus.

Although these devices are presented in different forms, all of them are generally comprise of layers of materials or structures. For example, in a transistor, it may consist of layers including an electrode layer, an insulator layer and a substrate layer, etc. The fabrication of each layer of these devices may require a precise dimension and a highly controlled purity such that the fabricated devices may operate as designed.

In order to achieve these requirements, fabrication of these layered structures may be carried out in a controlled environment, such as a fully enclosed chamber filled with inert gas or under vacuum. In addition, some fabrication processes may be accompanied with a high temperature condition for manipulating the physical/chemical properties of the layers of materials. Owing to these stringent fabrication steps, the production cost of each device is so high that rendering a high throughput fabrication being impossible.

### SUMMARY OF THE INVENTION

In accordance with a first aspect of the present invention, there is provided a method for fabricating a layer of material in an organic electronic structure, comprising the steps of: reducing moisture and oxygen content on a surface of a substrate; depositing the material contained in a solution on the surface of the substrate; and facilitating crystallization of the material contained in the solution applied on the surface so as to form the layer of material.

In an embodiment of the first aspect, the crystallization of the material is sensitive to moisture and oxygen content.

In an embodiment of the first aspect, the material includes a perovskite material.

In an embodiment of the first aspect, the material includes metal halide.

In an embodiment of the first aspect, the material includes a metal of at least one of Pb, Sn and Ge, and a halide of at least one of I, Br and/or Cl.

In an embodiment of the first aspect, the perovskite material includes a chemical structure of ABX3, wherein A is methylammonium and/or formamidinium; B is a metal and X is a halide.

In an embodiment of the first aspect, the layer of material includes a perovskite film.

In an embodiment of the first aspect, the method further comprises the step of preheating the material contained in the solution prior to depositing on the surface of the substrate.

In an embodiment of the first aspect, the step of reducing moisture and oxygen content on the surface of the substrate includes heating the substrate at a predetermined temperature.

In an embodiment of the first aspect, the substrate is heated at 80° C.

In an embodiment of the first aspect, the solution include dimethylformamide.

In an embodiment of the first aspect, the steps of depositing and facilitating crystallization of the material are carried out in an air ambient.

In accordance with a second aspect of the present invention, there is provided a perovskite precursor ink comprising a perovskite material contained in a solvent, wherein upon deposited on a surface of a substrate, the solvent is arranged to facilitate a reduction of moisture and oxygen content on the surface of the substrate, thereby facilitating crystallization of the perovskite material contained in the solvent applied on the surface so as to form a perovskite film.

In an embodiment of the second aspect, the perovskite material includes metal halide.

In an embodiment of the second aspect, the material includes a metal of at least one of Pb, Sn and Ge, and a halide of at least one of I, Br and/or Cl.

In an embodiment of the second aspect, the perovskite material includes a chemical structure of ABX₃, wherein A is methylammonium and/or formamidinium; B is a metal and X is a halide.

In an embodiment of the second aspect, the solvent includes dimethylformamide.

In an embodiment of the second aspect, the ink further comprises a low boiling point solvent including at least one of diethylether, chloroform, acetone, dichloromethane, pentane and ethyl ether.

In an embodiment of the second aspect, the low boiling point solvent is arranged to prevent an ingress of moisture and oxygen in the perovskite material and to facilitate a formation of a nanoporous structure of the perovskite film.

In an embodiment of the second aspect, the solvent is arranged to facilitate the reduction of moisture when upon the substrate being heated at a predetermined temperature.

In an embodiment of the second aspect, the substrate is heated at 80° C.

In accordance with a third aspect of the present invention, there is provided an organic electronic structure comprising an active layer of a perovskite film in accordance with the second aspect.

In an embodiment of the third aspect, the organic electronic structure further comprises a bottom electrode, a hole transporting layer, an electron transporting layer and a top metal electrode.

In an embodiment of the third aspect, the perovskite film is sandwiched between the hole transporting layer and the electron transporting layer.

In an embodiment of the third aspect, the bottom electrode is provided on a substrate including at least one of polyethylene terephthalate, polyethylene naphthalate, polyethersulfone and polycarbonate.

In an embodiment of the third aspect, the bottom electrode includes at least one of indium tin oxide, aluminum doped zinc oxide and indium doped zinc oxide.

In an embodiment of the third aspect, the hole transporting layer includes at least one of PEDOT:PSS, NiOₓ, MoOₓ, Poly-TPD, PTAA and GO.

In an embodiment of the third aspect, the electron transporting layer includes at least one of C₆₀, PC₆₁BM, PC₇₁BM, ICBA, N2200, ZnO.

In an embodiment of the third aspect, the top electrodes include at least one of aluminum, silver, gold and copper.

In an embodiment of the third aspect, the organic electronic structure includes a solar cell structure.

### BRIEF DESCRIPTION OF THE DRAWINGS

Embodiments of the present invention will now be described, by way of example, with reference to the accompanying drawings in which:

FIG. 1A is a set of scanning electron micrograph (SEM) showing the morphologies of PbI₂ films prepared under N₂ atmosphere with different humidity levels;

FIG. 1B is an illustration showing the crystallization mechanism of PbI₂ films prepared under an exposure of moisture or humid environment;

FIG. 1C is a set of optical images showing the PbI₂ films prepared under N2 atmosphere and in air with different humidity levels;

FIGS. 2A and 2B are optical images showing contact angles of PbI₂ solution on different substrates under N₂ atmosphere and N₂+O₂ atmosphere respectively;

FIG. 2C is a plot showing a correlation of PbI₂ solution wetting capability on various substrates and film deposition behaviour under different conditions;

FIG. 3A is an illustration of a film deposition process in accordance with an embodiment of the present invention;

FIG. 3B are optical images showing contact angles of PbI₂ solution on ITO/poly-TPD substrates under different deposition conditions;

FIG. 3C are optical images showing PbI₂ film deposited and formed on poly-TPD, PEDOT:PSS, and PTAA substrates with and without preheating;

FIGS. 3D and 3E are SEM images showing the morphologies of PbI₂ films and perovskite films prepared with preheating under ambient air condition;

FIG. 3F is a plot showing X-ray diffraction (XRD) patterns of PbI₂ and perovskite films prepared with preheating under ambient air condition;

FIG. 4A is a schematic diagram showing an organic electronic structure in accordance with an embodiment of the present invention;

FIG. 4B is an energy level diagram of the structure of FIG. 4A;

FIG. 4C is a plot showing a current-voltage characteristic of the device structure of FIG. 4A measured in the dark and under 100 mW/cm² photon flux, wherein the inset is the detailed photovoltaic performance;

FIG. 4D is a plot showing external quantum efficiency spectrum, internal quantum efficiency spectrum and the device reflectance profile of the device structure of FIG. 4A; and

FIG. 4E is a plot showing a comparison of the power conversion efficiency of the device of FIG. 4A with other referenced devices.

### DETAILED DESCRIPTION OF THE PREFERRED EMBODIMENT

The inventors have, through their own research, trials and experiments, devised that

Perovskite solar cells (PVSCs) includes organometal halide perovskite as a light harvesting material. The unique optoelectronic properties of perovskite materials such as high absorption coefficient, long charge carrier diffusion length and excellent charge carrier mobility. PVSC may achieve a power conversion efficiency (PCE) from 3.8% to 22.1%.

Despite the advances in PVSCs, there are still a lot of challenges that remain to be addressed, such as long-term stability, toxicity of lead, and harsh fabrication condition for reproducible efficiency. Among them, in order to achieve high efficiency and reproducibility, PVSCs are preferred to be fabricated in well-controlled inert glove box to exclude the water and oxygen from the environment. Such controlled environment may prevent PVSCs from achieving their large-scale manufacturing at low cost.

Air-processed PVSCs may be generally divided into two approaches: (i) searching for new perovskite materials with intrinsically good air stability and (ii) exploring novel preparation procedures to achieve reproducible high-quality films. For example, precursor materials for CH₃NH₃PbI₃₋ₓ(SCN)ₓ based pseudohalide and CsPbBr₃ based all-inorganic PVSCs may be fabricated in air, which may yield PCEs of 15.12% and 6.70%, respectively.

Alternatively, modified solution processed methods may be used fabricate PVSCs in air. For example, perovskite precursor film may be deposited via one-step spin-coating method in glovebox with subsequent annealing the film in ambient air with a relative humidity (RH) of around 35%. Moisture may facilitate ion diffusion in the precursor film, thus promoting the perovskite crystal growth. With the assistant of moisture, the device achieved a PCE of 17.1%. However, a well-controlled glovebox was still needed during the initial spin-coating of precursor materials and the fabrication of perovskite film was not fully air-processed.

In some example embodiments, preheating substrates may be employed as a method to fabricate perovskite films in air. For example, there is provided a one-step spin-coating method in which the preheating temperature may affect the thickness and quality of (FAPbI₃)₁₋ₓ(MAPbBr₃)-perovskite films. With a preheating condition at 50° C., a device based on mesoporous TiO₂ with 18.8% efficiency in the backward scan and 16.4% in the forward scan may be fabricated.

Alternatively, PVSC may be fabricated in air with mesoporous TiO2 structure using a two-step spin-coating method. PbI₂ may be difficult to be filled into the mesoporous TiO2 layer in air, resulting in bad coverage and device performance. By preheating the PbI₂ precursor solution before the PbI₂ deposition, the filling of PbI2 into the mesoporous structure may be improved with resulting smooth and compact film morphology. In this example, a device with PCE of 15.76% in ambient atmosphere (RH: 50%) may be fabricated.

The inventors researched on how the ambient air affects the formation of perovskite or PbI₂ films, and the causes of the improvement with the preheating method. Without wishing to be bound by theory, the moisture in air is believed to be the main factor influencing the perovskite film formation and thus the corresponding device performance.

In an example experiment, PbI₂ films were deposited by evaporation and then methylammonium iodide (MAI) was spin-coated on the PbI₂ films in an atmospheric bag with controlled RH from 1 to 60%. It is observed that the perovskite crystallization was strongly affected by the humidity level. At low RH (<20%), the perovskite film exhibits small cubic crystals and poor film coverage. However, when the RH was higher than 30%, the cubic crystal size became larger and the perovskite films exhibited smoother and more planar. In contrast, at a high RH of 60%, the cubic crystals became more rounded and the best substrate surface coverage was obtained. In this example, moisture may partially dissolve the precursor species and facilitate the ion diffusion within the film during crystallization.

In another example experiment, an opposite trend of moisture effect on perovskite films formation was observed. It was found that in order to obtain good film coverage, the RH had to be controlled at 30% or below. Less continuous morphologies of perovskite films were obtained when the RH was higher than 30%. It is believed that fast film formation may be induced by the moisture in air.

Based on the experimental results, the inventors devise that the perovskite crystallization and film formations are possibly not only sensitive to moisture, but also dependent on a number of factors such as the substrate condition, film preparation method, and other constituents in ambient air. However, the lack of systematic understanding into the environmental effects on PbI₂ or perovskite film and crystal formations may limit the development of air-processed PVSCs.

The inventors also researched on the impacts of both moisture and oxygen on the PbI₂ crystallization and film morphology in a humidity-controlled chamber filled with N₂ and air atmosphere.

In a two-step sequential deposition method, the morphology of the PbI₂ film may be important in determining the quality of the resulting perovskite film and hence the device photovoltaic performance. During the growth of the perovskite films, upon the deposition of MAI on the PbI₂ films, there is a volume expansion during the conversion reaction from PbI₂ to CH₃NH₃PbI₃ perovskite. Therefore, it is preferable that the morphology of the PbI₂ layer should be a continuous film with sub-micron size PbI₂ crystal grains with a high density of small pin-holes.

The inventors carried out an experiment to investigate the effect of moisture on PbI₂ film formation. For the study of film growth to correlate the film properties and device performance, the PbI₂ and perovskite films were deposited on a poly[N,N′-bis(4-butylphenyl)-N,N′-bis-(phenyl)benzidine] (poly-TPD)/ITO coated glass substrate. The effect with different interlayer materials was also studied.

It was found that a good morphology of the PbI₂ films with a good coverage and a high density of small pin-holes can be obtained when the humidity level is less than 20% RH. When the humidity level is higher than 20% RH, the PbI₂ films tend to form an isolated branching structure, Caused by the fast crystallization of PbI₂ induced by moisture at higher humidity levels.

However, in the one-step deposition approach where the two precursor materials PbI₂ and MAI were mixed in solution, it was not clear if the fast crystallization at a high humidity level was initiated in PbI2, MAI, or the resulting CH₃NH₃PbI₃ perovskite film.

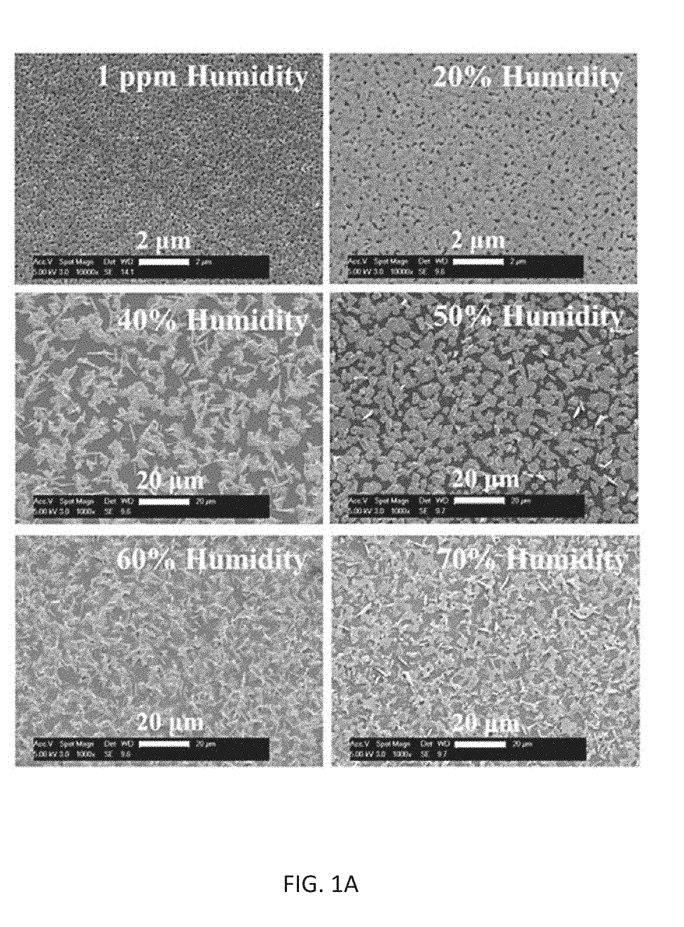

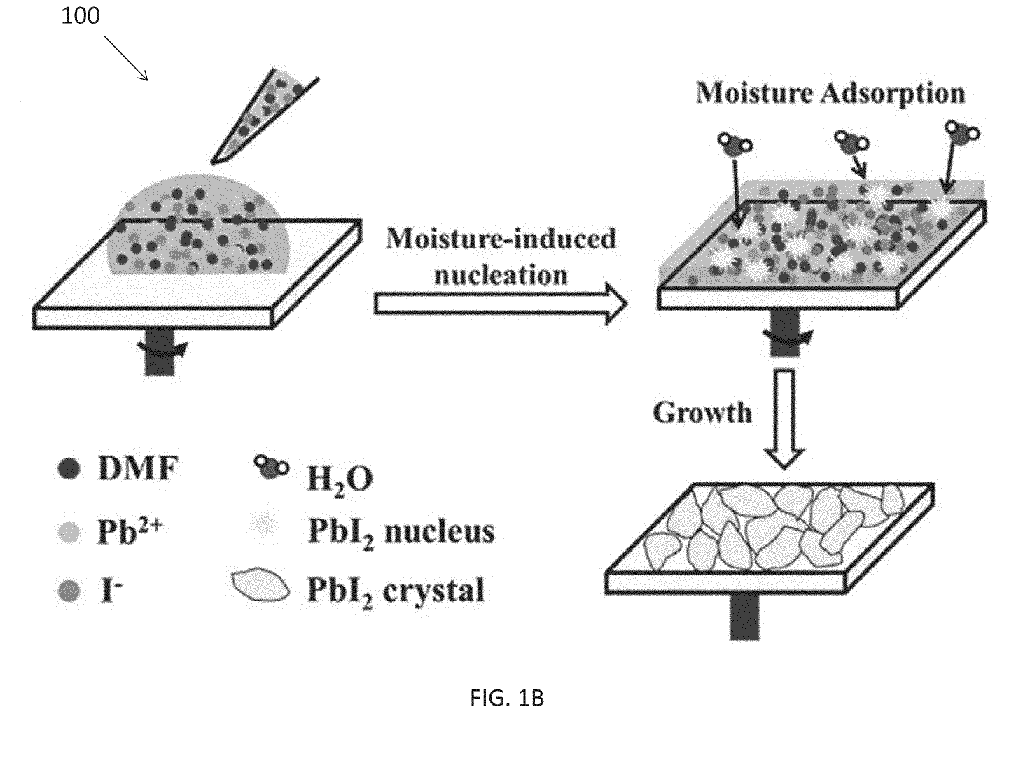

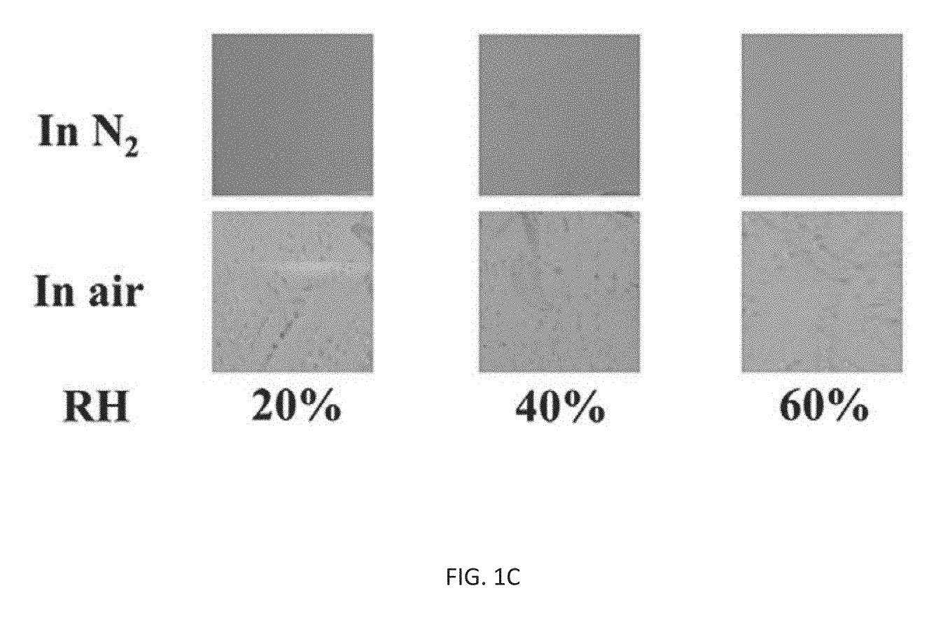

With reference to the SEM images as shown in FIG. 1A, it indicates that such a fast crystallization in a high RH has already been initiated in the PbI₂. As a control experiment, a small amount of water (10 mL) was added into a PbI₂ solution in N,N-Dimethylformamide (DMF) (DMF:water volume ratio is 200:1), and an immediate precipitation of PbI₂ was observed in less than one second.

The impact of moisture on PbI₂ film formation is further illustrated the process 100 in FIG. 1B which shows that water induced nucleation is a very fast process, it even happens right after dropping the PbI₂ solution on the substrate and during the spin-coating process. The DMF solvent also provides the mobility for the ions to form crystals. Therefore, large PbI₂ crystals are formed under a high RH level even during a short period spin-coating time of 30-60 s. However, after spin-coating, most of the DMF solvent is evaporated from the substrate and no further crystallization of PbI₂ has been observed.

Based on the above results, a preferred PbI₂ film morphology can be obtained when the RH level is 20% in N₂ atmosphere without oxygen.

The air processability of PbI₂ films was studied by purging ambient air with controlled RH levels inside a glove box. With reference to FIG. 1C, the PbI₂ solution was completely de-wetted from the substrate, and such an effect was even more severe than that with high RH level in nitrogen atmosphere. Despite that moisture plays the key role in determining the film forming of perovskite layers, the results suggest that other constituents in ambient air might also contribute to this severe de-wetting issue.

To further investigate the origin of the de-wetting of the PbI₂, a small amount of oxygen was introduced into the N₂ filled glove box with the RH level controlled at 20%. With the small amount of oxygen inside the glove box, the PbI₂ film has also completely de-wetted from the surface of the poly-TPD/ITO coated glass substrate. Compared to the films prepared in N₂, it is believed that oxygen is another detrimental factor affecting the PbI₂ film formation.

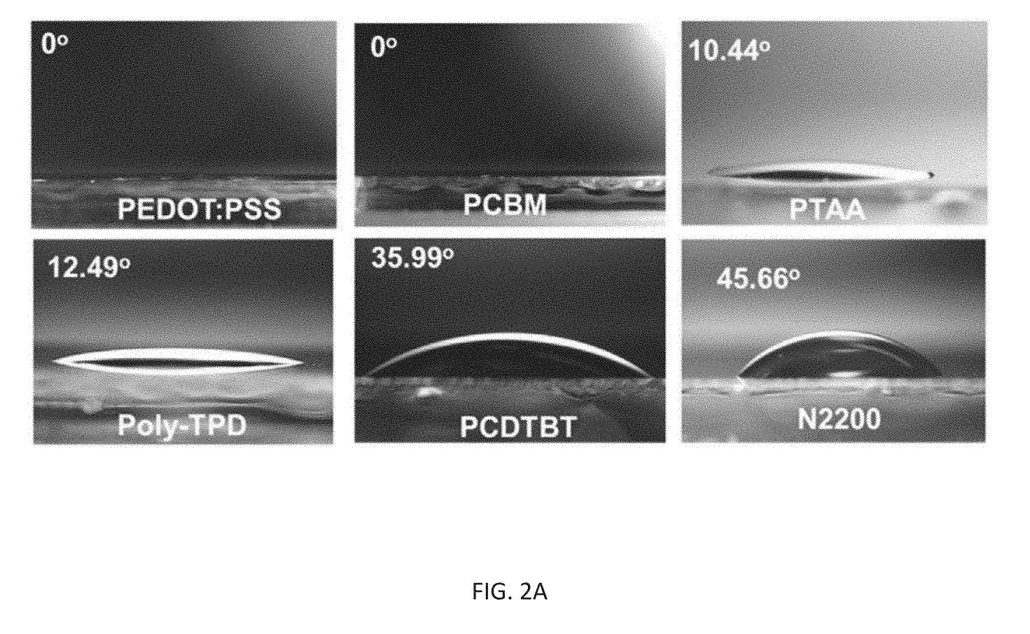

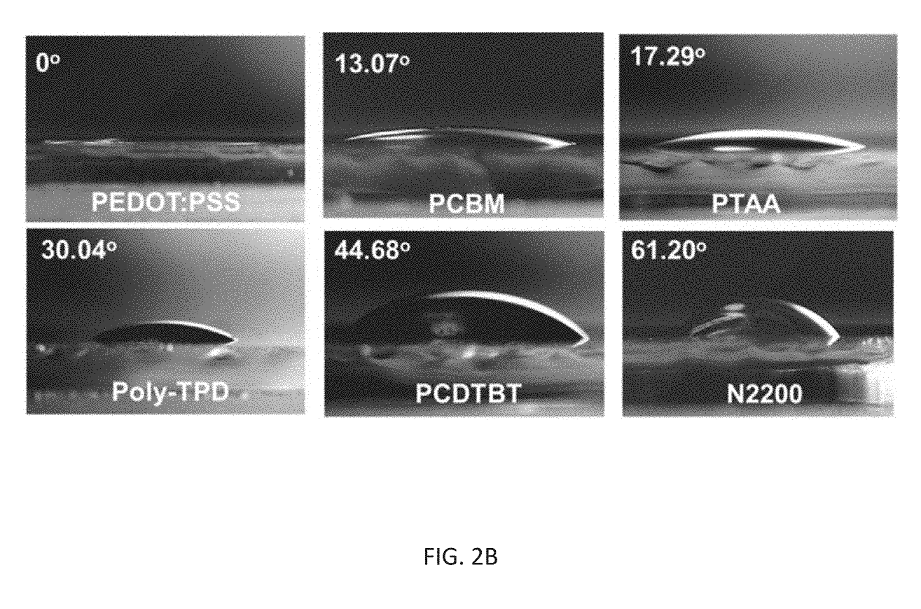

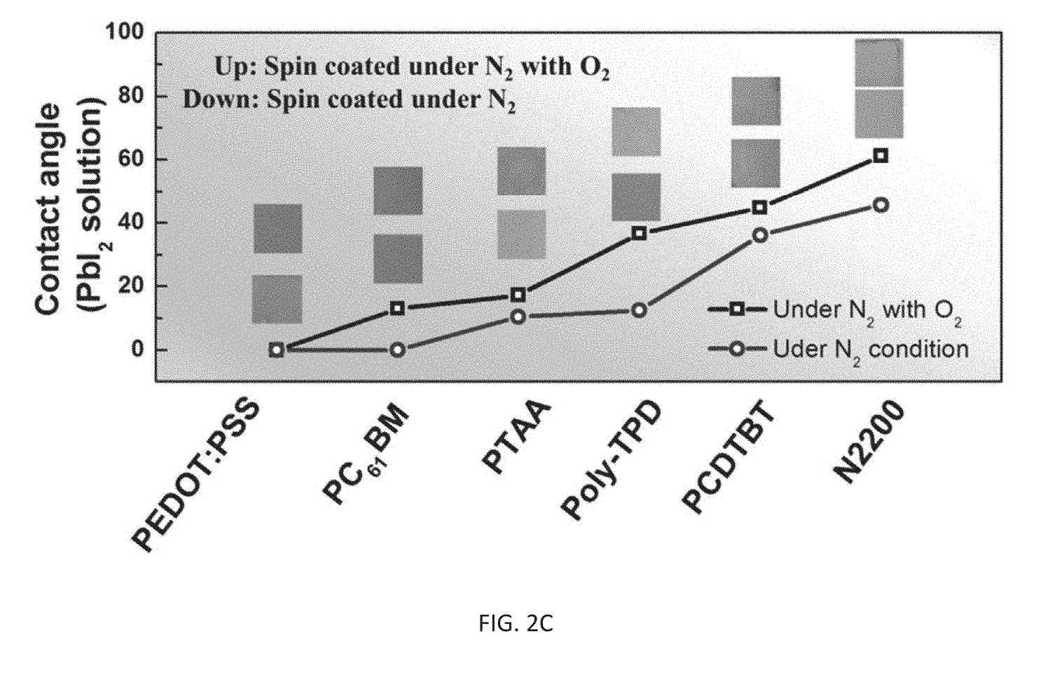

With reference to FIGS. 2A and 2B, there is shown the effect of oxygen on the PbI₂ film formation on different interlayer materials. The measured contact angles of the PbI₂-DMF solution dropped on substrates with different interlayer materials including poly(3,4-ethylenedioxythiophene) poly(styrenesulphonate) (PEDOT:PSS), [6,6]-phenyl C₆₁-butyric acid methyl ester (PC₆₁BM), poly-TPD, Poly(triaryl amine) (PTAA), poly[N-9″-hepta-decanyl-2,7-carbazole-alt-5,5-(4′,7′-di-2-thienyl-2′,1′,3′- benzothiadiazole) (PCDTBT) and poly([N,N′-bis(2-octyldodecyl)-1,4,5,8-naphthalene diimide-2,6-diyl]-alt-5,5′-(2,2′-bithiophene)) (N2200) inside a glove box with pure N₂ (FIG. 2A) and small amount of oxygen (FIG. 2B), respectively.

The contact angle was measured using PbI₂ solution with DMF solvent dropped on different interlayer surfaces, which is significantly different from the contact angles measured using water. It was observed that an increase of the contact angles of the PbI₂-DMF solution on hydrophobic organic interlayers with oxygen, compared to that measured under N₂ condition without oxygen.

The difference in contact angles and photographs of the deposited films are summarized in the plot as shown in FIG. 2C. Considering the PbI₂ films deposited in pure N₂, except PCDTBT and N2200, continuous and uniform PbI2 films can be obtained with a contact angle less than 15°. More importantly, it was observed that the contact angle of the PbI₂ solution on the substrate of about 30° appears to be the critical condition for uniform film formation. When the contact angle is larger than 30°, the PbI₂-DMF solution would be totally de-wetted from the substrate and the PbI₂ film cannot form on the substrate.

To exclude the effects from the organic solvent, dimethyl sulfoxide (DMSO) was also used as solvent to dissolve PbI₂, and the contact angles in N₂ and N₂+O₂ atmosphere were measured respectively. It was observed that the contact angle measured in N₂+O₂ atmosphere is larger than that measured in N₂, which further confirms the oxygen induced de-wetting phenomenon. Since both contact angles are larger than 30°, the PbI₂ (dissolved in DMSO) film cannot be deposited on poly-TPD/ITO substrates neither in glove box nor in ambient air. This result further supports the speculation that oxygen is the cause to the observed de-wetting issue when depositing PbI₂ on the poly-TPD/ITO coated glass in ambient air.

Based on the above results, the inventors devise the origin of the detrimental effect on PbI₂ film formation in ambient air: (i) the moisture induces fast crystallization of PbI₂, leading to a poor film coverage and isolated branching grain growth and (ii) oxygen alters the surface energy of the interlayer materials and thereby results in de-wetting of PbI₂ solution on the substrates, especially on hydrophobic organic materials.

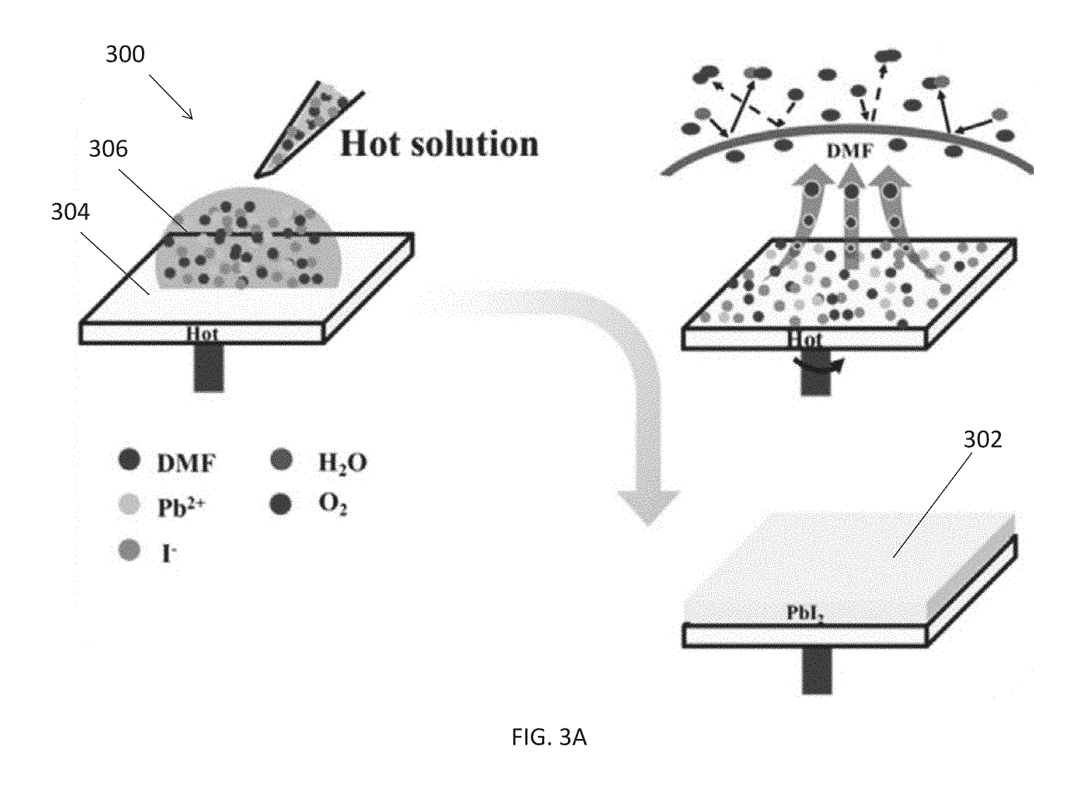

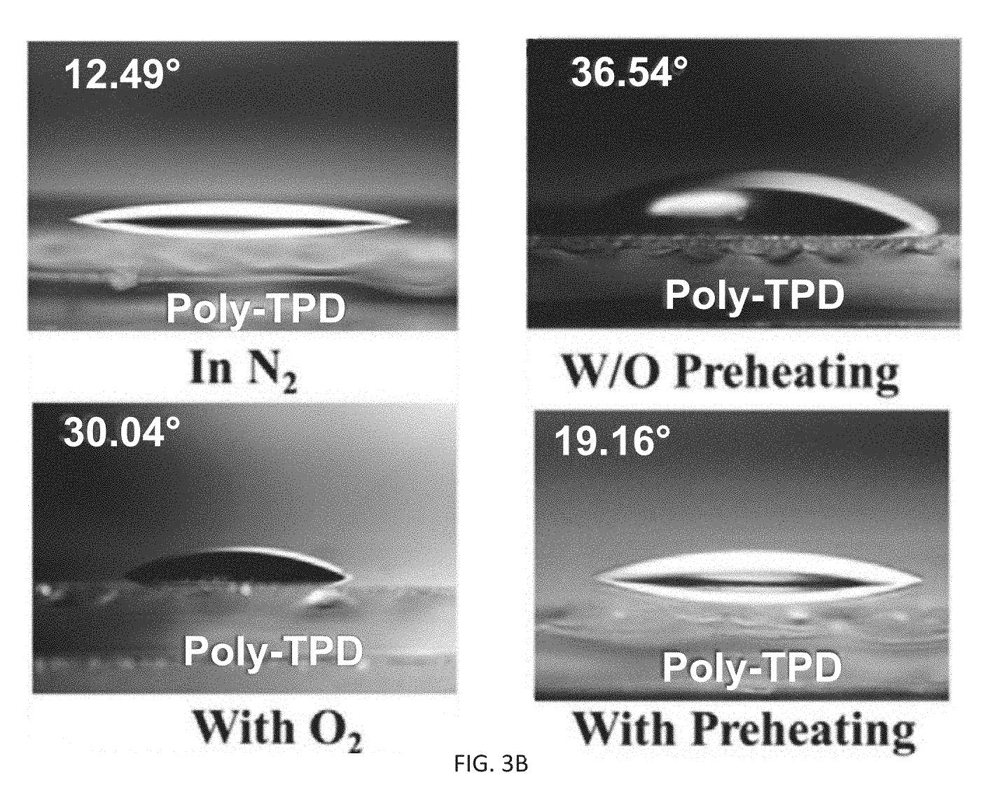

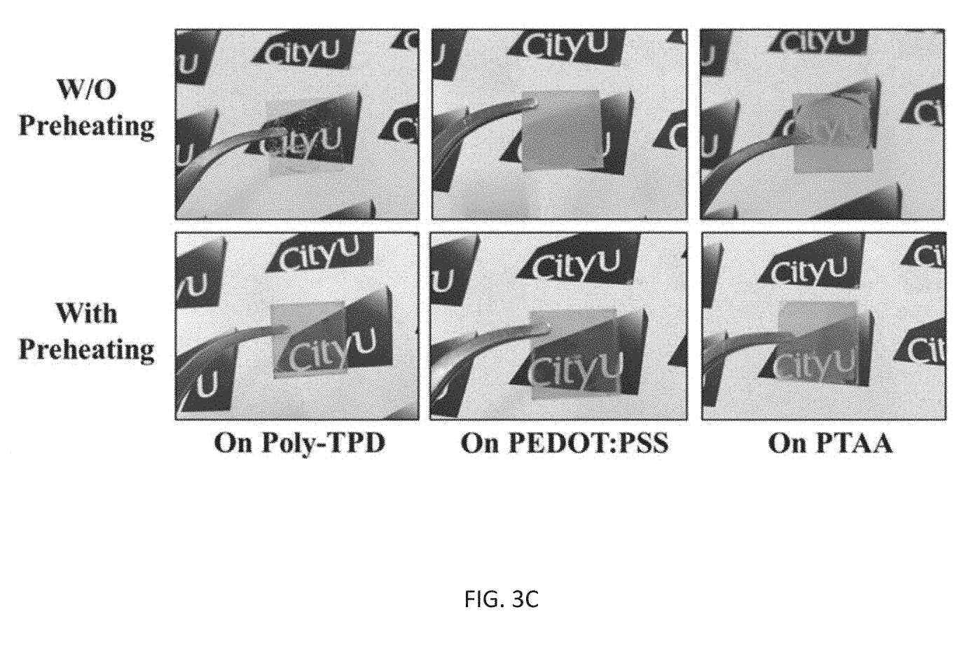

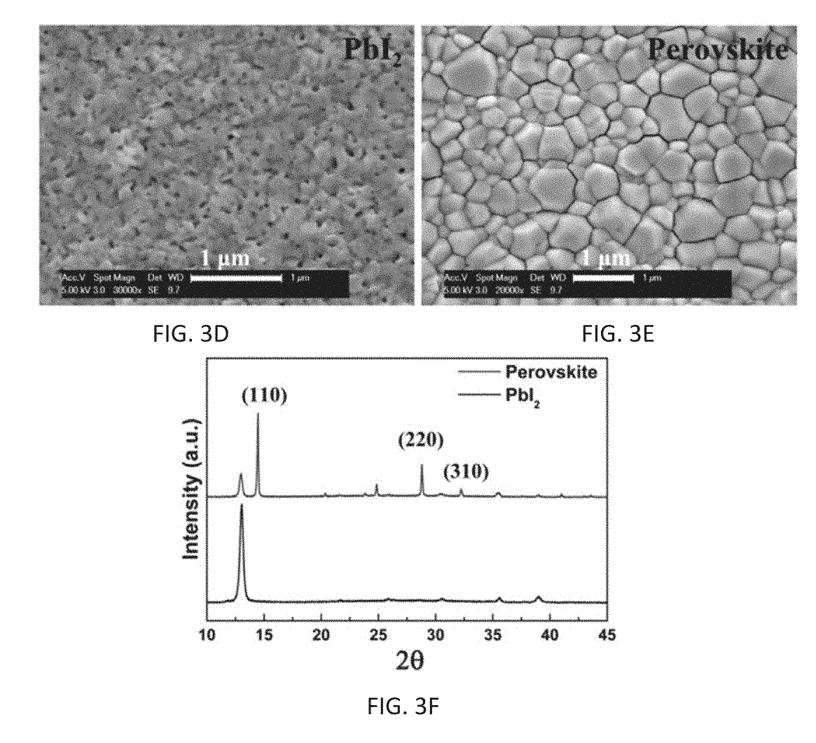

With reference to FIG. 3A, there is shown an embodiment of a method 300 for fabricating a layer of material 302 in an organic electronic structure, which may be used in fabricating a perovskite material layer or a perovskite film which is the light absorbing layer in a PVSC structure.

In this embodiment, the method comprising the steps of: reducing moisture and oxygen content on a surface of a substrate 304; depositing the material contained in a solution 306 on the surface of the substrate 304; and facilitating crystallization of the material contained in the solution 306 applied on the surface so as to form the layer of material 302.

Referring to also FIG. 3B, the contact angle of PbI₂ solution on poly-TPD under N₂ atmosphere without oxygen is 12.49° which is smaller than that measured under condition with oxygen (30.04°). Therefore, the failure of depositing PbI₂ film on poly-TPD in air mainly stems from the de-wetting of poly-TPD driven by oxygen in air.

As discussed earlier in the disclosure, the crystallization of the perovskite material is sensitive to moisture and oxygen content, thus by reducing moisture and oxygen content on the substrate 304 the deposition and crystallization of the perovskite material on the substrate 304 may be carried out in an air ambient, or an environment which may be rich in oxygen content and/or moisture, which is not preferable in organic electronic device fabrication.

Understanding the factors limiting the growth of the PbI₂ films, it is preferable that both the moisture and oxygen impacts can be reduced by building up a vapor shield. Preferably, the method includes heating the substrate 304 at a predetermined temperature so as to reduce moisture and oxygen content on the surface of the substrate 304. Alternatively or additionally, the material contained in the solution 306 may be preheated prior to depositing on the surface of the substrate 304.

Preferably, by simultaneously heating up the substrate 304 and PbI₂ solution 306 during the deposition to oppose the in-diffusion of the two components, the crystallization process of the perovskite material may be well controlled, which results in an optimal morphology of the perovskite film 302 formed on the surface.

To facilitate the crystallization of the perovskite material, in this example embodiment, the perovskite precursor ink 306 includes N,N-Dimethylformamide (DMF) and/or other low boiling point solvents including diethylether, chloroform, acetone, dichloromethane, pentane or ethyl ether. Preferably, the low boiling point solvent may prevent ingress of moisture and oxygen in the perovskite material so as to facilitate a formation of a nanoporous structure of the perovskite film 302.

The perovskite material may include PbI₂ or other metal halide. For example, the material includes a metal of Pb, Sn and/or Ge, and a halide of I, Br and/or Cl. In addition, the perovskite material may include a chemical structure of ABX₃, wherein A is methylammonium (MA) and/or formamidinium (FA), B is a metal and X is a halide.

Preferably, the substrate 304 and/or the perovskite precursor ink 306 may be preheated at 80° C., prior to the deposition of the ink 306 on the substrate 304. Upon depositing the (preheated) PbI₂ solution 306 on a preheated substrate, both the water and oxygen molecules absorbed on the substrate surface will be released due to heating. At the same time, although the boiling point of DMF is high (153° C.), the kinetic energy of solvent molecules may still follow the Maxwell-Boltzmann distribution with more DMF molecules escapes from liquid phase at higher temperature. Thus reduces the probability of ingress of water and oxygen molecules into the PbI₂ film 302 during spin coating.

Advantageously, a dense PbI₂ film 302 on poly-TPD can be formed in air-ambient processing environment. The contact angles of room temperature and preheated PbI₂ solution (80° C.) on poly-TPD substrates in air were measured. It is observed that the preheating method in accordance with the embodiments of the present invention is a preferable method for improving the wetting property of PbI₂ solution 306 on the poly-TPD surface in air, as the contact angle was reduced from 36.54° without preheating to 19.16° with preheating.

With reference to FIG. 3C, by using the preheating method, the detrimental impacts of moisture and oxygen on PbI₂ film formation may be reduced and preferable PbI₂ film morphology may be obtained on both poly-TPD, PEDOT:PSS, and PTAA coated substrates in ambient air. Without preheating, the PbI₂ film cannot be deposited on poly-TPD because it is suffered from the oxygen induced de-wetting issues. Similarly, in case of depositing on PEDOT:PSS and PTAA, the PbI2 films are rough and diffusive, it is mainly due to the moisture induced fast crystallization of PbI₂. On the other hand, with preheating, all the films become bright and transparent, which is an indication of smooth and uniform films properties as discussed earlier. Advantageously, these preferred embodiments provide effective methods which may be applied on various substrates to facilitate air-processed PVSCs.

With reference to FIGS. 3D and 3E, high-magnification SEM images of PbI₂ and perovskite films prepared with 80° C. preheating temperature are illustrated. A dense PbI₂ film on poly-TPD may be obtained, which consequently lead to a uniform perovskite film with average grain size about 500 nm. The XRD patterns of these films are illustrated in FIG. 3F which shows that there is still a little amount of residual PbI₂ in the perovskite film, which may be beneficial for the device photovoltaic performance by traps passivation at the grain boundaries.

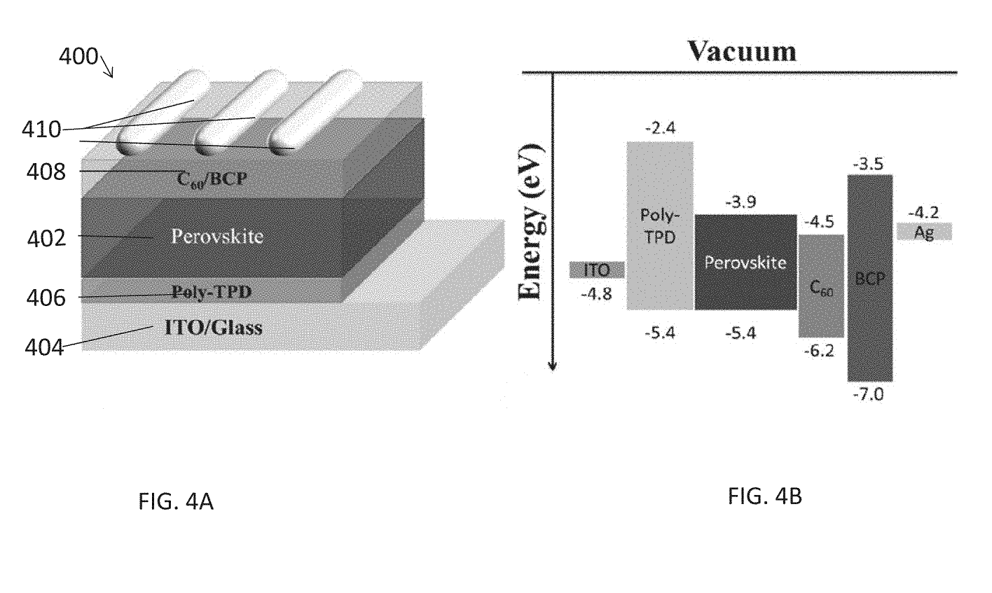

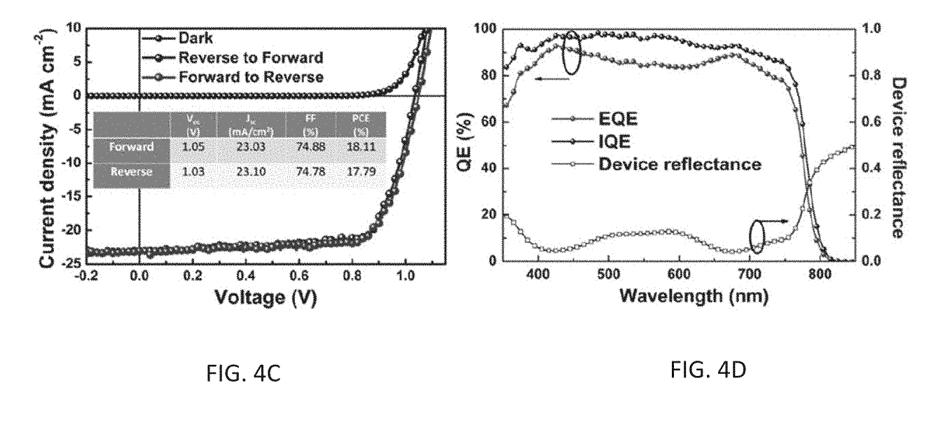

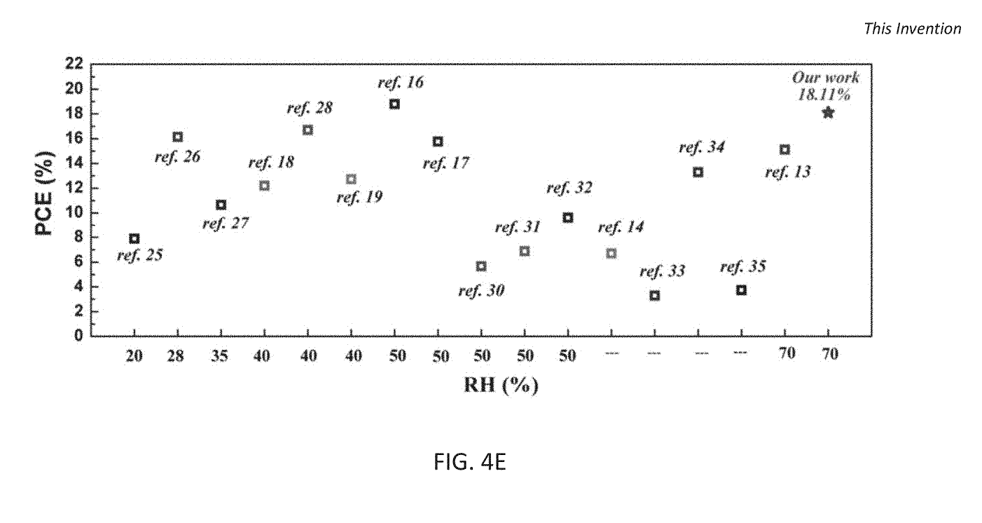

With reference to FIG. 4A, there is shown an example embodiment of an organic electronic structure 400, such as an organic photovoltaic device or a perovskite solar cell structure. The electronic structure 400 comprises an active layer of a perovskite film 402 which may be fabricated using the perovskite precursor ink 306 and the preheating method 300 as discussed.

In this embodiment, the organic electronic structure 400 further comprises a bottom electrode 404, a hole transporting layer 406, an electron transporting layer 408 and a top metal electrode 410. The perovskite film 402 is sandwiched between the hole transporting layer 406 and the electron transporting layer 408 such that carriers from excited electron-hole pairs may be collected by the electrodes (410, 404) via the electron/hole transporting layers.

Preferably, the organic electronic structure 400 may include a normal/standard structure or an invented structure as appreciated by a skilled person, and the structure may be provided on a flat or flexible substrate such as but not limited to glass, polyethylene terephthalate, polyethylene naphthalate, polyethersulfone and polycarbonate substrate.

On the substrate, transparent conductive layers 404 may be provided such that light may pass through the conductive layer 404 to reach the light absorbing layer 402 such as the perovskite film. Preferably, conductive metal oxides such as indium tin oxide, aluminum doped zinc oxide and indium doped zinc oxide may be provided on the glass or flexible substrate as bottom electrode 404. The bottom electrode 404 may be patterned prior to deposition of the layers of the electronic device structure 400.

Referring to FIGS. 4A and 4B, the thin film device includes a structure of ITO/poly-TPD/Perovskite/C₆₀/BCP/Ag. Firstly, a layer of poly-TPD served as a hole transporting material (HTM) 406, such as PEDOT:PSS, NiOₓ, MoOₓ, Poly-TPD, PTAA and GO, may be deposited on top of patterned ITO glass substrates 404.

The process is followed by the fabrication of the perovskite active layer 402 via a two-step spin-coating method in air with the preheating method 300 as described above. After thermal annealing, an electron transporting layer 408, such as but not limited to C₆₀, PC₆₁BM, PC₇₁BM, ICBA, N2200 or ZnO may be deposited on the perovskite active layer 402.

Finally, a BCP hole blocking layer and an Ag electrode 410 may be deposited on top of perovskite film 402 by thermal evaporation, respectively. The top electrodes 410 may alternatively include aluminum, gold or copper based on different design of the structures or work function matching with the transporting layers.

Compared to the HTM PEDOT:PSS, the highest occupied molecular orbital (HOMO) of poly-TPD is closer to the valence band (VB) of CH₃NH₃PbI₃ perovskite (5.4 eV), which may increase the open circuit voltage (V_{oc}) of the solar cell.

The inventors fabricated a PVSC using the methods and perovskite precursor ink in accordance with the embodiments of the present invention. In the experiment, chemicals for perovskite preparation such as lead iodide (PbI₂) and methylammonium iodide (MAI) from Acros Organics and Dyesol, organic solvents such as anhydrous N,N-dimethylformamide (DMF), dimethyl sulfoxide (DMSO), and anhydrous 2-propanol (IPA) from Sigma-Aldrich, and the hole transporting material poly-TPD from Xi'an Polymer Light Technology Corp. were used.

An example device fabrication process is summarized as follows: the patterned ITO glasses were cleaned with decon 90 and deionized water and then dried in an oven. Before device fabrication, the cleaned ITO glasses were further treated in an ultraviolet-ozone cleaning system for 20 min. Afterwards, the poly-TPD (4 mg/ml in chlorobenzene) solution was dropped on the ITO surface and spun with the speed of 6000 rpm for 40 s, and then annealed at 110° C. for 10 min to form a thin hole transporting layer. The poly-TPD film was placed under UVO treatment for 10 s before perovskite film deposition.

The perovskite film was prepared by a two-step method. Before the PbI₂ film deposition, the ITO/poly-TPD substrate, the PbI₂ solution (461 mg mL⁻¹ in DMF) and the holder of the spin-coater were preheated at 80° C. for more than 15 min to reduce the temperature drop during the spin-coating process. Then the hot PbI₂ solution was dropped on the hot ITO/poly-TPD substrate and spun at 4000 rpm for 40 s immediately. The as-prepared PbI2 film was then dried at 70° C. for 10 min. To form the perovskite film, methylammonium solution (35 mg mL⁻¹ in IPA) was dropped on the PbI₂ film and then spun at 4000 rpm for 40 s. Finally, the stacked precursor layers were annealed at 100° C. for 1 h to form the perovskite film. All the preparation processes were conducted in ambient air with 70% humidity.

The following deposition of fullerene C₆₀ (20 nm), 2,9-dimethyl-4,7-diphenyl-1,10-phenanthroline (BCP: 5 nm), and Ag electrode (80 nm) on the top of the perovskite film were conducted by thermal evaporation. The effective area of the solar cell was measured to be 0.1 cm⁻².

With reference to FIG. 4C, there is shown the current-voltage (J-V) characteristics of the device fabricated in ambient air with humidity as high as 70% under dark and one sun conditions in accordance with the embodiments of the present invention. The J-V from forward voltage bias to reverse voltage bias back and forth with a scan rate of 25 mVs⁻¹, which resembles a quasisteady-state condition, and the device has negligible hysteresis behavior. The highest PCE achieved by scanning from forward bias to reverse bias is 18.11% with a V_{oc} of 1.05 V, a short-circuit current density (J_{sc}) of 23.03 mAcm⁻², and a fill factor (FF) of 74.88%. The detailed photovoltaic parameters are summarized inset the J-V curve.

Advantageously, the stabilized PCE of the PV device is around 17.7%. It was observed that the performance of the air-processed PVSCs is highly reproducible with an average PCE of 16.2%. With reference to FIG. 4E, it is shown that the PCE of 18.11% with negligible hysteresis is one of the best performance achieved by solution-processed PVSCs in air when compared with other reference devices. In addition, the external quantum efficiency (EQE) spectrum shows strong photoresponse over 85% from 400 to 750 nm, which is consistent with the absorption spectra of perovskite film. The calculated J_{sc} from integrating the EQE spectrum is 21.79 mAcm⁻², which is slightly lower than that obtained from J-V results with a mismatch within 5%.

To further confirm the EQE results, the device reflectance was measured. The low reflectance from 400 nm to 750 nm implies the high absorption of the device, resulting in the preferred EQE profile. The internal quantum efficiency (IQE) spectrum is extracted by the EQE and device reflectance results according to the equation EQE=(1−device reflectance)×IQE. Referring to FIG. 4D, the IQE is over 90% across a substantial proportion of the device absorption spectrum, indicating the efficient charge carriers generation and collection processes within our air-processed PVSCs.

These embodiments may be advantageous in that organic electronic devices may be fabricated in air-ambient, such as large area perovskite solar cell may be fabricated using roll-to-roll process or doctor blading in ambient air without the use of sophisticated vacuum equipment.

Advantageously, with the air-processed perovskite ink, solar cell can be fabricated by high throughput roll-to-roll technique, which leads to large area and flexible solar cell fabrications with lower manufacturing cost.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

Any reference to prior art contained herein is not to be taken as an admission that the information is common general knowledge, unless otherwise indicated.

1. A method for fabricating a layer of material in an organic electronic structure, comprising the steps of:
reducing moisture and oxygen content on a surface of a substrate;
depositing the material contained in a solution on the surface of the substrate; and
facilitating crystallization of the material contained in the solution applied on the surface so as to form the layer of material.

2. The method for fabricating a layer of material in accordance with claim 1, wherein the crystallization of the material is sensitive to moisture and oxygen content.

3. The method for fabricating a layer of material in accordance with claim 1, wherein the material includes a perovskite material.

4. The method for fabricating a layer of material in accordance with claim 3, wherein the material includes metal halide.

5. The method for fabricating a layer of material in accordance with claim 4, wherein the material includes a metal of at least one of Pb, Sn and Ge, and a halide of at least one of I, Br and Cl.

6. The method for fabricating a layer of material in accordance with claim 3, wherein the perovskite material includes a chemical structure of ABX₃, wherein A is methylammonium and/or formamidinium; B is a metal and X is a halide.

7. The method for fabricating a layer of material in accordance with claim 1, wherein the layer of material includes a perovskite film.

8. The method for fabricating a layer of material in accordance with claim 1, further comprising the step of preheating the material contained in the solution prior to depositing on the surface of the substrate.

9. The method for fabricating a layer of material in accordance with claim 1, wherein the step of reducing moisture and oxygen content on the surface of the substrate includes heating the substrate at a predetermined temperature.

10. The method for fabricating a layer of material in accordance with claim 9, wherein the substrate is heated at 80° C.

11. The method for fabricating a layer of material in accordance with claim 1, wherein the solution include dimethylformamide.

12. The method for fabricating a layer of material in accordance with claim 1, wherein the steps of depositing and facilitating crystallization of the material are carried out in an air ambient.

13. A perovskite precursor ink comprising a perovskite material contained in a solvent, wherein upon deposited on a surface of a substrate, the solvent is arranged to facilitate a reduction of moisture and oxygen content on the surface of the substrate, thereby facilitating crystallization of the perovskite material contained in the solvent applied on the surface so as to form a perovskite film.

14. The perovskite precursor ink in accordance with claim 13, wherein the perovskite material includes metal halide.

15. The perovskite precursor ink in accordance with claim 14, wherein the material includes a metal of at least one of Pb, Sn and Ge, and a halide of at least one of I, Br and Cl.

16. The perovskite precursor ink in accordance with claim 13, wherein the perovskite material includes a chemical structure of ABX₃, wherein A is methylammonium and/or formamidinium; B is a metal and X is a halide.

17. The perovskite precursor ink in accordance with claim 13, wherein the solvent includes dimethylformamide.

18. The perovskite precursor ink in accordance with claim 17, further comprising a low boiling point solvent including at least one of diethylether, chloroform, acetone, dichloromethane, pentane and ethyl ether.

19. The perovskite precursor ink in accordance with claim 18, wherein the low boiling point solvent is arranged to prevent ingress of moisture and oxygen in the perovskite material and to facilitate a formation of a nanoporous structure of the perovskite film.

20. The perovskite precursor ink in accordance with claim 13, wherein the solvent is arranged to facilitate the reduction of moisture when upon the substrate being heated at a predetermined temperature.

21. The perovskite precursor ink in accordance with claim 20, wherein the substrate is heated at 80° C.

22. An organic electronic structure comprising an active layer of a perovskite film in accordance with claim 13.

23. The organic electronic structure in accordance with claim 22, further comprising a bottom electrode, a hole transporting layer, an electron transporting layer and a top metal electrode.

24. The organic electronic structure in accordance with claim 23, wherein the perovskite film is sandwiched between the hole transporting layer and the electron transporting layer.

25. The organic electronic structure in accordance with claim 23, wherein the bottom electrode is provided on a substrate including at least one of polyethylene terephthalate, polyethylene naphthalate, polyethersulfone and polycarbonate.

26. The organic electronic structure in accordance with claim 23, wherein the bottom electrode includes at least one of indium tin oxide, aluminum doped zinc oxide and indium doped zinc oxide.

27. The organic electronic structure in accordance with claim 23, wherein the hole transporting layer includes at least one of PEDOT:PSS, NiOx, MoOx, Poly-TPD, PTAA and GO.

28. The organic electronic structure in accordance with claim 23, wherein the electron transporting layer includes at least one of C₆₀, PC₆₁BM, PC₇₁BM, ICBA, N2200, ZnO.

29. The organic electronic structure in accordance with claim 23, wherein the top electrodes include at least one of aluminum, silver, gold and copper.

30. The organic electronic structure in accordance with claim 23, wherein the organic electronic structure includes a solar cell structure.
